(19) United States
(12) Patent Application Publication
(10) Pub. No.: US 2026/0095026 A1
(43) Pub. Date: Apr. 2, 2026

(54) HYBRID III-V SILICON OPTICAL DEVICES WITH OXIDE-BASED CURRENT CONFINEMENT

(71) Applicant: Intel Corporation, Santa Clara, CA (US)

(72) Inventors: Guan-Lin Su, Sunnyvale, CA (US); Duanni Huang, San Jose, CA (US); Harel Frish, Albuquerque, NM (US); John Heck, Berkeley, CA (US); Haisheng Rong, Pleasanton, CA (US)

(73) Assignee: Intel Corporation, Santa Clara, CA (US)

(21) Appl. No.: 18/900,505

(22) Filed: Sep. 27, 2024

(51) Int. Cl. H01S 5/34; H01S 5/026; H01S 5/30; H01S 5/343

(52) U.S. Cl. CPC H01S 5/341; H01S 5/026; H01S 5/3086; H01S 5/34313

(57) ABSTRACT

Hybrid III-V silicon device structures including a silicon optical waveguide of a first width, a III-V semiconductor mesa of a second width and a current channel of a third width that is smaller than the second width. The third width may be only slightly larger than the first width to narrowly confine electrical current directly over the optical waveguide while the second width is significantly larger than the first width to efficiently transport heat away from the optical gain medium. The current channel has low electrical resistivity and one or more material layers within the mesa are converted to a compound comprising aluminum (Al) and oxygen (O) having higher electrical resistivity. A mesa may be fabricated from a III-V material stack comprising one or more Al-rich layers, which are preferentially oxidized to form resistive aluminum oxide regions that laterally encroach a center of the mesa where current is confined.

### BACKGROUND

Photonic integrated circuits (PICs) are increasingly important in high-performance computing, data center, and cloud computing applications. The use of silicon in photonics (SiPh), enables high-volume, low-cost and highly integrated PICs. The provisioning of on-chip active optical devices, such as lasers, is a critical path in PIC development, particularly for applications relying on dense wavelength division multiplexing (DWDM). Along with lower manufacturing costs, integration of active optical devices directly on silicon would reduce coupling losses for SiPh applications.

A “hybrid silicon” active optical device heterogeneously integrates III-V material with a silicon substrate comprising an optical waveguide. Active optical devices include an optical gain medium with some examples including lasers and semiconductor optical amplifiers (SOAs). For hybrid optical device architectures, the gain (active) material may be in the form of quantum dots or quantum wells, for example.

New hybrid silicon active optical device architectures offering improved performance and/or enabling hybrid silicon active optical devices to be assembled with advanced packaging technology would be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram of methods for fabricating a hybrid silicon optical device, in accordance with some embodiments;

FIG. 2A is a plan view of a silicon PIC substrate, in accordance with some embodiments;

FIG. 2B is a cross-sectional profile view of a silicon PIC substrate, in accordance with some embodiments;

FIG. 3A is a cross-sectional profile view of a III-V P-i-N diode structure comprising one or more layers of active material, in accordance with some embodiments;

FIG. 3B is an expanded cross-sectional profile view of the p-type portion of the P-i-N diode structure introduced in FIG. 3A illustrating an Al-rich material layer, in accordance with some embodiments;

FIGS. 3C, 3D, 3E and 3F are cross-sectional profile views of p-type material layers having different Al content, in accordance with some embodiments;

FIG. 4 is a cross-sectional profile view illustrating formation of a hybrid silicon structure, in accordance with some embodiments;

FIGS. 5, 6, and 7 illustrate cross-sectional profile views of a hybrid silicon optical device structure evolving during practice of the methods shown in FIG. 1, in accordance with some embodiments;

FIG. 8 illustrates a plan view of a hybrid silicon optical device, in accordance with some embodiments;

FIG. 9 illustrates a cross-sectional profile view of a hybrid silicon optical device, in accordance with some further embodiments;

FIG. 10 illustrates a mobile computing platform and a data server machine comprising a silicon PIC including a plurality of hybrid silicon optical devices, in accordance with some embodiments; and

FIG. 11 is a functional block diagram of an electronic computing device, that may implement one or more of the components of the mobile platform or data serve machine illustrated in FIG. 10, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The inventors have found that optical gain efficiency, gain saturation threshold and/or other performance characteristics of an active hybrid silicon optical device may be improved without greatly increasing thermal impedance of the device by selectively oxidizing one or more III-V semiconductor material layers. According to embodiments herein, laser self-heating and/or thermal rollover effects where laser output declines sharply as laser current increases may be reduced by controlling the electrical resistivity of one or more thin layers of III-V material through their partial oxidation whereby a portion of the material layer(s) outside of the current channel is converted into a compound comprising oxygen (i.e., an oxide).

According to embodiments herein, a hybrid silicon device structure may include a silicon optical waveguide of a first width, a III-V semiconductor mesa of a second width, and a current channel of a third width that is smaller than the second width. The third width may be only slightly larger than the first width to narrowly confine electrical current directly over the optical waveguide while the second width is significantly larger than the first width allowing the semiconductor material mesa to efficiently transport heat away from an optical gain medium. While the current channel within an unoxidized portion of a III-V material mesa may retain a low electrical resistivity, an edge portion of one or more Al-rich material layers in the mesa are converted into a compound comprising Al and O (e.g., an AlOₓ-(III)-(V) compound) having higher electrical resistivity. Since these electrically resistive layer portions may be only a few tens of nanometers thick, their effect on thermal impedance of the mesa thickness is negligible. Furthermore, since these electrically resistive layers are thermally stable, embodiments described herein are insensitive to subsequent heating of the hybrid silicon optical device, for example during fabrication or packaging of the optical device, or during operation of the optical device.

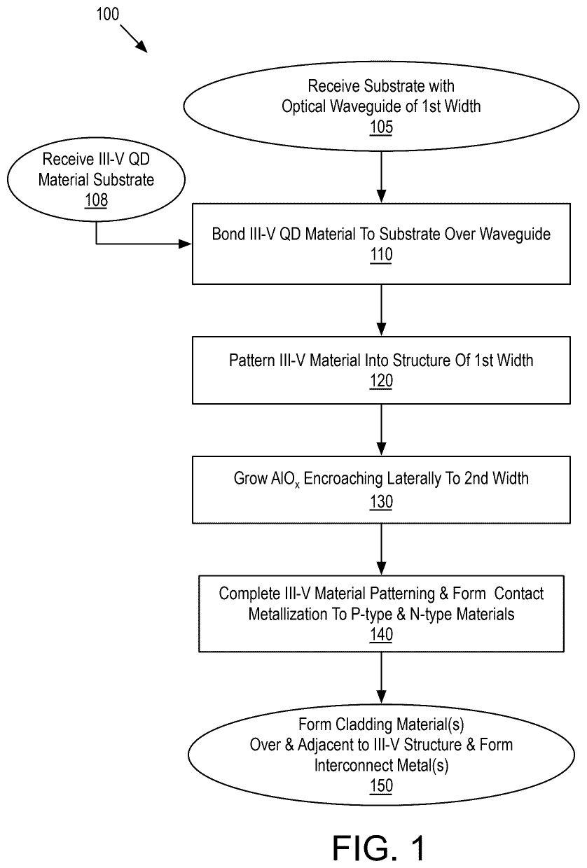

FIG. 1 is a flow diagram of methods 100 for fabricating a hybrid silicon active optical device, such as an SOA or laser, in accordance with some embodiments. Methods 100 may be practiced, for example, to fabricate a hybrid silicon quantum dot laser (HSQDL) having one or more of the structural attributes described herein. Methods 100 may also be practiced to fabricate other hybrid silicon devices, such as a quantum well laser or a semiconductor optical amplifier, that face similar self-heating challenges and/or may similarly benefit from electrical current confinement. In some exemplary embodiments, methods 100 integrate an HSQDL within one or more photonic integrated circuits (PICs), and more specifically within one or more silicon photonic chips. Although many examples are further described in the context of HSQDL implementations, the exemplary architectures may instead be applied to alternative hybrid silicon optical devices, or even non-hybridized optical devices, without departing from the principles disclosed herein.

Methods 100 begin at input 105 where a substrate is received. In exemplary hybrid-silicon embodiments, the substrate received includes silicon. The substrate received at input 105 at least one optical waveguide that has been fabricated upstream of methods 100 according to any technique(s) known in the art. The substrate may further comprise one or more other passive optical devices, such as (de)multiplexers, grating couplers, etc. The substrate may also comprise active components such as modulators and/or photodetectors. Such optical devices may have been fabricated into the substrate upstream of methods 100 according to any technique(s) known in the art. Such optical devices may also be fabricated downstream of methods 100.

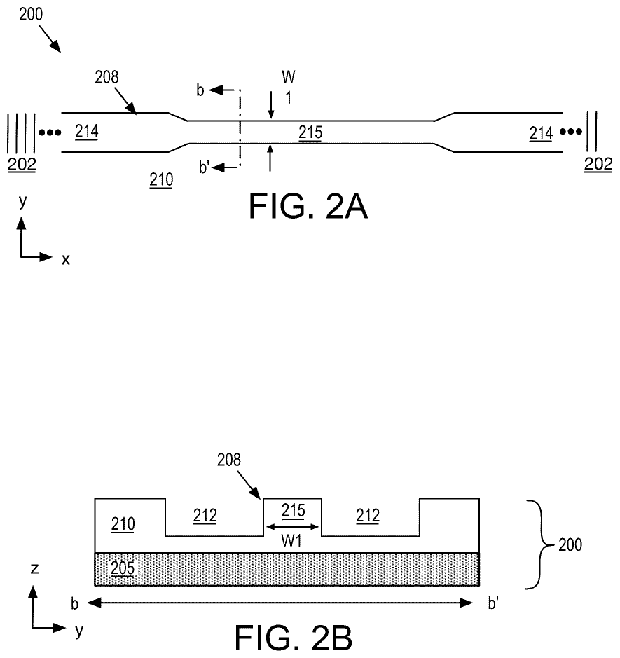

FIG. 2A is a plan view of a monolithic silicon PIC substrate 200, in accordance with some laser embodiments. FIG. 2B is a cross-sectional profile view of silicon PIC substrate 200 through the b-b′ plane demarked by the dot-dashed line in FIG. 2A, in accordance with further embodiments. In some examples, substrate 200 is a workpiece having a diameter of at least 300 mm but may also be of any other dimension(s). Substrate 200 includes a substantially planar optical waveguide 208 patterned within a substrate material layer 210 or within a thin film on substrate material layer 210. In exemplary embodiments where substrate material layer 210 comprises substantially monocrystalline silicon, waveguide 208 is also substantially monocrystalline silicon. In other embodiments, waveguide 208 is predominantly silicon and nitrogen (e.g., Si₃N₄). In some examples illustrated by FIG. 2B, substrate material layer 210 is a top layer of a semiconductor-on-insulator (SOI) substrate material stack further comprising an insulator material layer 205. In exemplary embodiments, where substrate material layer 210 is substantially pure silicon, insulator material layer 205 is advantageously predominantly silicon and oxygen (e.g., SiO₂). One or more additional substrate material layers (not depicted) may be under, or on a back side of, insulator material layer 205. In some SOI embodiments, insulator material layer 205 is on a bulk layer of substantially pure (mono)crystalline silicon.

Optical waveguide 208 may have any suitable architecture, such as, but not limited to, a substantially planar ridge waveguide of the type having the profile illustrated in FIG. 2B. In the examples further illustrated by FIG. 2A, optical waveguide 208 has a substantially constant transverse lateral width W1 (e.g., in y-dimension) over a longitudinal length (e.g., in x-dimension) of an active waveguide region 215. At opposite ends of active waveguide region 215, waveguide 208 tapers out to passive waveguide regions 214 having a larger transverse width. Although the active waveguide lateral width W1 may vary, in some exemplary silicon waveguide embodiments width W1 is in the range of 150 nm to 1 μm. A similar range is also applicable to the z-height (z-axis in FIG. 2B) of at least active waveguide region 215. Air 212 is over a surface of PIC substrate 200 and adjacent to sidewalls of waveguide 208.

Although implementations may vary, for laser device embodiments at least a portion of optical waveguide 208 may comprise a mirror for establishing a resonant optical cavity within active waveguide region 215, for example according to any suitable Fabry-Perot (FP) laser architecture. In the illustrated embodiment, grating structures 202 are defined within passive waveguide regions 214, for example according to any suitable Distributed Bragg Reflector (DBR) laser architecture. In alternative architectures (e.g., a Distributed Feedback (DFB) laser architecture), one or more grating structures 202 may be located within active waveguide region 215. The illustrated mirror structures may be absent from other active optical device embodiments (e.g., SOAs).

Returning to FIG. 1, at input 108 a donor substrate comprising a gain medium, such as multiple quantum well (MQW) material layers or quantum dot (QD) material layers, is received. In exemplary hybrid silicon embodiments, the gain medium comprises III-V semiconductor material. The III-V material stack and/or donor substrate advantageously has dimensions compatible with those of the PIC substrate and may comprise any suitable mechanical support material layer(s). The III-V material stack is advantageously substantially monocrystalline. The III-V material stack may have any number of material layers, one or more of which may have a chemical composition(s) and a micro/nano structure known to be suitable as MQW or QD optical gain medium within one or more predetermined bands of the electromagnetic energy spectrum.

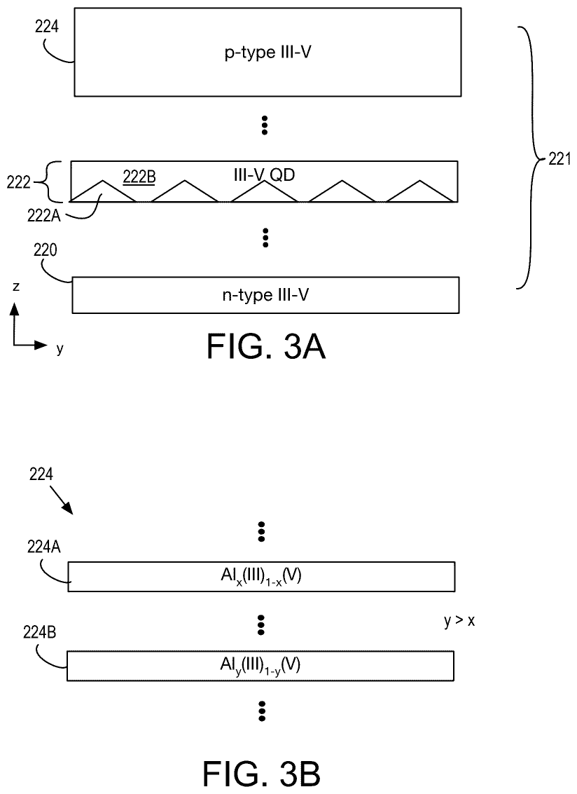

FIG. 3A illustrates a cross-sectional profile view of a III-V material stack 221 that may be received as part of a donor substrate. As shown, material stack 221 includes a P-i-N diode structure comprising at least one optical gain material layer 222, in accordance with some embodiments. Gain material layer 222 is between an n-type material 220 and a p-type material 224. Material stack 221 is advantageously an epitaxial heterostructure that may have any number of gain material layers (represented by ellipses) between n-type material 220 and p-type material 224. Each optical gain material layer may have any thickness, with 5-50 nm being an exemplary thickness range.

In accordance with some embodiments, material layers of material stack 221 all comprise a Group III-V crystalline alloy material (i.e., a III-V material stack). In some examples, optical gain material layer 222 comprises quantum dots 222A of predominantly In and As, which may be binary InAs. Gain material layer 222 may further comprise a spacer material 222B of another III-V alloy having a distinct chemical composition with a suitable optical band offset and/or lattice mismatch with that of quantum dots 222A. The chemical composition of gain material layer 222 may be varied over a range of binary, ternary or quaternary III-V alloys having a wide range of layer thicknesses, and/or nanostructures for an optical gain within a particular photon energy band. In some embodiments where quantum dots 222A are predominantly In and As, spacer material 222B has more Ga than quantum dots 222A (e.g., spacer material 222B is InGaAs while quantum dots 222A are binary InAs). In other embodiments, gain material layer 222 may comprise a InGaAsP MQW or QD structure. These embodiments are suitable for an IR band around 1330-1550 nm.

N-type material 220 and p-type material 224 may comprise one or more electrically active impurity dopants, which may vary with the majority constituents of materials 220, 224. For example, in some embodiments where materials 220 and 224 are both binary or ternary alloys including Ga and As, n-type material 220 may comprise carbon, beryllium, magnesium, zinc, or cadmium while p-type material 224 may comprise silicon, tellurium or carbon. Electrically active impurity dopant concentrations may vary with implementation to achieve any bulk electrical resistivity suitable for the application. Thicknesses of material 220, 224 may also vary with implementation. In some exemplary embodiments, n-type material 220 has a layer thickness (e.g., z-axis) of 5-500 nm while p-type material 224 has a layer thickness of 1-2 μm.

As also represented by the ellipses in FIG. 3A, material stack 221 may further include a separate confinement structure located between gain material layer 222 and either (or both) of the impurity-doped materials 220, 224. A separate confinement structure may have any architecture known to be suitable for the active optical device and may comprise a heterostructure including at least one wide bandgap, low refractive index material layer. In some examples where material stack 221 includes a separate confinement structure between gain material layer 222 and each of impurity-doped materials 220 and 224, the separate confinement structure comprises a quaternary III-V alloy, such as InGaAlAs and/or InGaAsP with significantly lower impurity dopant concentration than that of material layers 220, 224.

In exemplary embodiments, material stack 221 comprises a first material layer with greater aluminum (Al) content than a second material layer. As described further below, inclusion of one or more Al-rich material layers within material stack 221 enables a subsequent preferential oxidation of the Al-rich material layer(s) relative Al-lean material layer(s) of material stack 221. As the oxidation rate of a III-V material comprising Al is a function of the aluminum concentration, an extent of oxidation across layers of III-V material may be controlled by varying the amount of Al during epitaxial growth of material stack 221 (e.g., upstream of methods 100).

FIG. 3B is an expanded cross-sectional profile view of p-material 224 including both an Al-lean material layer 224A and an Al-rich material layer 224B. Al-lean material layer 224A comprises Alₓ(III)₁₋ₓ(V), where x is a first atomic (at.) percentage (%) of Al with one or more other Group III lattice constituents (e.g., In or Ga) making up the balance of 1-x. The Group V lattice constituents of Al-lean material layer 224A may include one or more of As, P, or Sb, for example. Al-rich material layer 224B comprises Al_{y}(III)_{1-y}(V) where y is a second, larger, atomic percentage of Al with one or more other Group III lattice constituents (e.g., In or Ga) making up the balance of 1-y. The Group V lattice constituents of Al-rich material layer 224B may similarly include one or more of As, P, or Sb, for example.

In exemplary embodiments, Al content of Al-rich material layer 224B is at least 2 at. % greater than the Al content of Al-lean material layer 224A. In some further embodiments, Al-rich material layer 224B comprises at least 90 at. % Al and may advantageously comprise 90-98 at. % Al. In some examples, Al is substantially absent from Al-lean material layer 224A (i.e., x is 0). In other embodiments x is non-zero.

As represented by the ellipses in FIG. 3B, p-material 224 may include any number of Al-rich material layers 224B interspersed among any number of Al-lean layers 224A. Although aluminum content may vary within each of one or more Al-lean material layers and may similarly vary within each of one or more Al-rich material layers, each Al-rich material layer 224B present has a higher Al content than each Al-lean material layer 224A. FIG. 3C is cross-sectional profile view of an embodiment where p-type material 224 comprises a plurality of Al-lean layers 224A as well as a first Al-rich layer 224B and a second Al-rich layer 224C, each having different Al content. Al-rich layer 224A comprises Al_{z}(III)_{1-z}(V) where z is a third atomic percentage of Al, which is advantageously greater than y.

In exemplary embodiments, Al content of Al-rich material layer 224C is at least 2 at. % greater than the Al content of Al-rich material layer 224B. In some further embodiments, both Al-rich material layers 224B and 224C comprise at least 90 at. % Al and may advantageously both comprise 90-98 at. % Al. Although two Al-rich material layers are illustrated in FIG. 3C, there may be any number of Al-rich material layers separated from each other by an intervening Al-lean material layer. In some embodiments, there are 3-10 Al-rich material layers separated from each other by an intervening Al-lean material layer. As further illustrated in FIG. 3C, Al-rich material layer 224B has an as-grown thickness T1 and Al-rich material layer 224C has an as-grown thickness T2. Although thicknesses T1 and T2 need not be equal and each may vary with implementation, in some embodiments thicknesses T1 and T2 are each in the range of 25-50 nm.

FIG. 3D is a cross-sectional profile view of p-type material 224 in accordance with some specific GaAs-based embodiments. For the AlGaAs crystalline material system where lattice constant is a weak function of aluminum content, Al concentration between material layers 224A, 224B and 224C may vary anywhere from 0 at. % to 98 at. %. FIG. 3E further illustrates a specific example where x is zero and Al-lean material layer 224A is binary GaAs. For such embodiments, Al-rich material layer 224B is Al_{y}Ga_{1-y}As and Al-rich material layer 224C is Al_{z}Ga_{1-z}As where z is greater than y. For some such embodiments, z is greater than y by at least 0.02 and both z and y may be 0.9, or more, without inducing excessive lattice mismatch from binary GaAs.

FIG. 3F is a cross-sectional profile view of p-type material 224 in accordance with some alternative InAs-based embodiments. For the AlInAs crystalline material system where lattice constant is a stronger function of aluminum content, Al concentration between material layers 224A, 224B and 224C may vary to a lesser extent than for the GaAs system if pseudomorphic lattice matching (i.e., monocrystallinity) of p-type material 224 is desired. However, Al-lean material layer 224A may advantageously comprise InₓGa₁₋ₓAs, where x may be varied for sufficient lattice match an Al-rich material layer 224B comprising Al_{y}In_{1-y}As having an Al content of y.

Although FIG. 3B-3F illustrate specific examples of p-type material 224, a similar variation may be implemented within n-type material of a P-i-N diode stack for alternative optical device embodiments. For example, where material layer ordering within III-V material stack 221 (FIG. 3A) is altered (inverted, etc.) either or both of p-type material 224 and n-type material 220 may be epitaxially grown to have both Al-lean and Al-rich material layers.

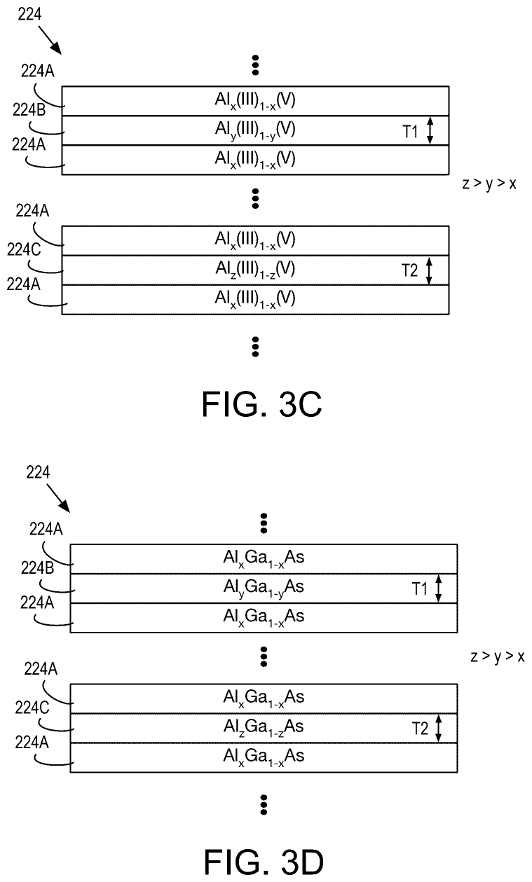

Returning to FIG. 1, methods 100 continue at block 110 where a material stack including non-silicon material layers is transferred from the donor substrate received at input 108 to the PIC substrate received at input 105. Any substrate (wafer)-level film bonding process may be practiced at block 110 to form a hybrid material heterostructure. The term “hybrid” is in reference to resulting structure including non-silicon (e.g., III-V) material layers bonded to underlying silicon (or a silicon-based thin film material layer thereon). Once bonded, the donor substrate may be removed to complete transfer of the non-silicon material layers. FIG. 4 is a cross-sectional profile view illustrating formation of a HSQDL workpiece 400, in accordance with some embodiments where material stack 221 is bonded over PIC substrate 200. As shown, bonding process 415 places n-type material 220 proximal to optical waveguide 208 and p-type material 224 distal from waveguide 208. In the illustrated example, n-type material 220 is in direct contact with waveguide active region 215. However, one or more intervening material layers (not depicted) may instead be between n-type material 220 and waveguide active region 215. In the illustrated example, material stack 221 bridges over air 212 and extends over an adjacent (perimeter) portion of substrate material layer 210. However, other waveguide cladding structures are possible.

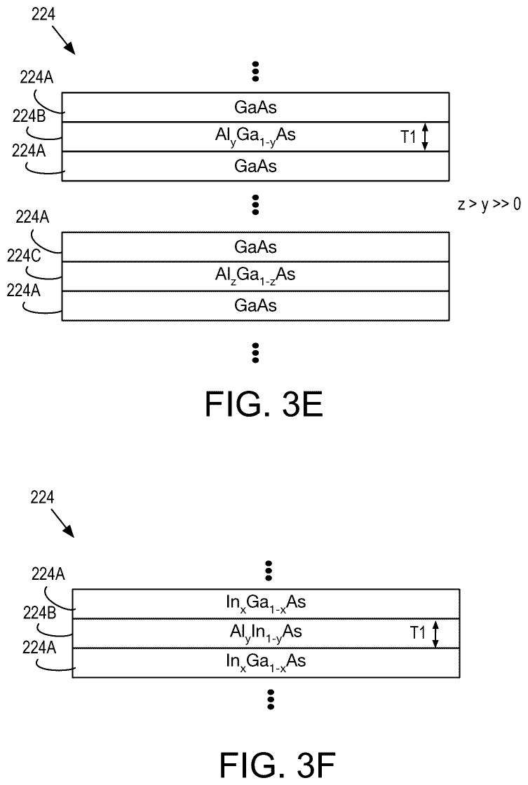

Following the formation of a hybrid silicon-III/V structure, active optical device fabrication continues at block 120 where at least some of the III-V material layers bonded at block 110 are patterned into a structural feature. In the example further illustrated in FIG. 5, one or more etch processes have defined an HSQDL structure 500 that includes a III-V mesa structure with a sidewall 524 etched according to a patterned etch mask 627. As shown, at least p-type material layers 224 have been etched into a mesa structure having a minimum transverse mesa lateral width W2. Mesa (top) width W2 is significantly greater than active optical waveguide transverse lateral width W1. Increasing mesa width W2 will reduce the thermal resistance of HSQDL structure 500. Advantageously, mesa lateral width W2 is substantially centered with waveguide lateral width W1. Although mesa width W2 may vary with implementation, in some embodiments is 10 μm, or more. As shown in FIG. 5, material layers 220 and 222 may not be etched during an initial mesa patterning.

At block 130, at least an edge portion of one more Al-rich material layers within the structural feature defined at block 120 are preferentially oxidized, converting the portion of Al-rich III-V material into an aluminum oxide compound that has a higher electrical resistivity than an unoxidized portion of the Al-rich material layer(s). By converting a perimeter portion of the structural feature into an electrical insulator, electrons may be confined within the dimensionally larger structural feature advantageous for the high thermal conductivity associated with semiconductor materials.

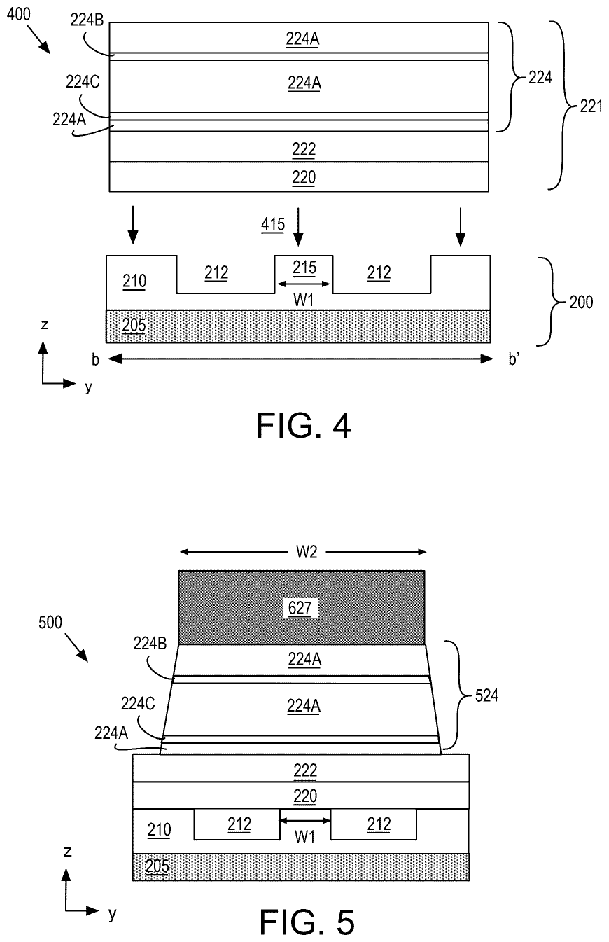

In the example further illustrated in FIG. 6, HSQDL structure 500 is exposed to an oxidation process 529. In some advantageous embodiments, oxidation process is a thermal oxidation process, and more advantageously a wet oxidation process, whereby mesa sidewall 524 is exposed to water vapor at a high temperature (e.g., 400° C., or more). Optionally, the oxidation process may also be at an elevated pressure. As illustrated in FIG. 6, a perimeter portion of Al-rich material layers 224B and 224C proximal to sidewall 524 is converted (i.e., oxidized) into an aluminum oxide edge material layer 630 preferentially relative to Al-lean material layer 224A. The oxide edge material layer 630 is confined to the as-grown thickness of the Al-rich material layer, and therefore oxide edge material layer 630 is not only coplanar with the Al-rich material layer from which it is grown but is also approximately the same thickness T₁ (e.g., 25-50 nm) as the Al-rich material layer from which it is grown.

As further illustrated in FIG. 6, aluminum oxide edge material layer 630 extends from sidewall 524 into the mesa by a lateral encroachment depth or distance. Encroachment distance varies as a function of Al content within Al-rich material layers 224B, 224C. For example, at least within the range of 90-98 at. % Al, the rate of thermal oxidation of III-V alloys varies approximately by one-half for each difference of 2 at. % Al. In the illustrated example where Al-rich material layer 224C has a higher Al content than Al-rich material layer 224B, the aluminum oxide edge material layer 630 coplanar with the leaner Al-rich material layer 224B has a first encroachment distance E₁, which is smaller than a second encroachment distance E₂ of aluminum oxide edge material layer 630 coplanar with the richer Al-rich material layer 224C. Although encroachment distance E₁ may vary, in some embodiments encroachment distance E₁ is at least 500 nm, and may be 1 μm, or more.

By tuning the Al-content of various Al-rich material layers included within p-type material 224, encroachment distances (depths) can be controlled to provide a particular current confinement size, for example relative to optical waveguide width W₁. The electron confinement profile may also be controlled limit current crowding effects within p-type material 224. In exemplary embodiments, where Al-rich material layer 224C has a higher Al content than Al-rich material layer 224B, an unoxidized central region of Al-rich material layer 224B has a lateral width W₃ that is smaller than top mesa width W₂ by approximately twice encroachment distance E₁ but is wider than lateral width W₄ of an unoxidized central region of Al-rich material layer 224C. In a further example where Al-rich material layer 224B is at least 90 at. % and Al-rich material layer 224C has approximately 2 at. % more Al, encroachment distance E₁ is approximately one-half of encroachment distance E₂ so that lateral width W₄ is smaller than lateral width W₃ by approximately twice encroachment distance E₁. Although only two Al-rich layers 224B, 224C are illustrated, any number of additional Al-rich layers may implement a similar trend of greater lateral electron confinement with closer proximity to the underling silicon optical waveguide.

For embodiments where Al-lean material layer(s) 224A is free of Al, there is negligible oxide growth/encroachment within Al-lean material layer(s) 224A. However, for embodiments where Al-lean material layer(s) 224A also comprises Al, some measurable aluminum oxide material growth may occur during the wet oxidation process albeit to a much lesser extent than for Al-rich material layers 224B, 224C. As further shown in the expanded view of sidewall 524 (FIG. 6), an aluminum oxide material 630 may be present at sidewall 524 along any Al-lean material layer(s) 224A that also comprises Al. Encroachment distance E₀ may therefore vary with Al content of Al-lean material layer(s) 224A from zero to some examples where E₀ is 10-50 nm, or more. Despite being much shallower in depth than the aluminum oxide material layers formed from aluminum-rich layers, the non-zero depth may nevertheless provide advantageous termination of surface states along the mesa edge, which may, for example, reduce shunt leakage paths.

Although an electrical insulator, aluminum oxide edge material layer 630 also has a relatively high thermal conductivity (e.g., K value of 15-35 Wm⁻¹K⁻¹). Furthermore, the layer thickness (e.g., along z-axis) of aluminum oxide edge material layer 630 is limited by the as-grown Al-rich III-V material layer thickness, which may be only 25-50 nm/layer, for example and therefore only a small fraction of the total thickness of the III-V material mesa. Accordingly, aluminum oxide edge material layer 630 may contribute very little to the thermal resistance of HSQDL structure 500. Notably, aluminum oxide edge material layer 630 also has a low refractive index (e.g., 1.6-1.7), which may further serve to enhance optical mode confinement within the HSQDL structure 500 and thereby further improve performance of the active optical device.

Accordingly, electrical resistivity of a portion of one or more Al-rich layers 224A, 224B is modulated through their preferential oxidation to a define an electrical current channel that is significantly smaller in lateral width than the lateral width of the patterned semiconductor material mesa comprising an aluminum oxide edge material layer 630. By modulating III-V material layers 224B, 224C to have a higher Al content during an epitaxial growth process, oxidation of those material layers within perimeter portion of the mesa significantly increases the electrical resistivity of the perimeter portion of the mesa, thereby confining the electrical current channel to the lateral widths W₃, W₄, etc. Hence, for exemplary embodiments illustrated in FIG. 6 where p-type material 224 is distal from the silicon optical waveguide, modulation of the electrical resistivity of a portion of p-type material 224 entails oxidizing a perimeter portion of Al-rich material layer 224B and or 224C selectively over Al-lean material layer 224A to tailor a channel width of p-type material 224 retaining low electrical resistivity over the thickness of p-type material 224. In the specific example illustrated in FIG. 6, the Al content of Al-rich material layers increases with proximity to the underlying silicon optical waveguide to gradually increase confinement of current passing through p-type material 224 during operation of HSQDL structure 500, as further described below. For alternative structures where the material stack 221 is inverted from that illustrated in FIG. 6, a similar technique can be practiced on n-type material layer 220.

Returning to FIG. 1, methods 100 continue at block 140 where remaining layers of III-V material may be patterned. Such supplemental patterning may be unnecessary where oxidation at block 130 poses no issue. However, for embodiments where a gain material layer or n-type material also has significant Al content, patterning process(es) may avoid exposing these layers until after the oxidation process. Following definition of the III-V material structure, device contact metallization may be formed at block 140 to complete an active optical device structure. For an exemplary III-V material mesa, a first contact (e.g., p-contact) metallization feature may be formed over a top surface of p-type material in the III-V mesa while a second contact (e.g., n-contact) metallization feature may be formed on n-type material adjacent to the III-V material mesa.

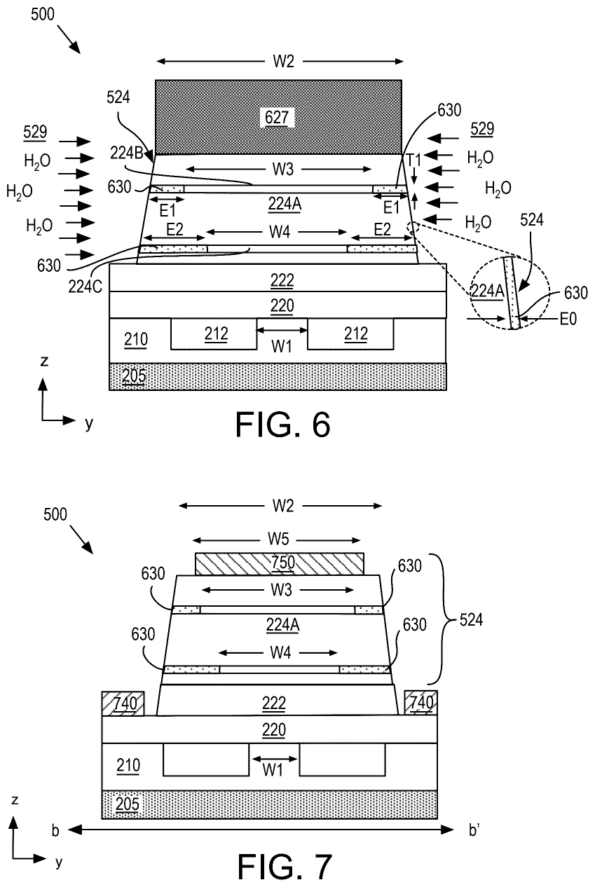

In the example illustrated in FIG. 7, a contact metallization feature 740 is in direct contact with n-type material 220 adjacent to mesa sidewall 524, which has been extended through the thickness of gain material layer 222. Contact metallization feature 740 may have any chemical composition known to be suitable for an ohmic or tunneling electrical contact to n-type material 220. Another contact metallization feature 750 is in direct contact with p-type material 224. Contact metallization feature 750 may have any chemical composition known to be suitable for an ohmic or tunneling electrical contact to p-type material 224.

As further shown in FIG. 7, contact metallization feature 750 may overlap electrically resistive aluminum oxide edge material layer 630. In this example, contact metallization feature 750 is vertically spaced apart from aluminum oxide edge material layer 630 by a thickness of one or more Al-lean p-type material layer 224A. As shown, contact metallization feature 750 has a lateral contact width W5 that is significantly greater than minimum current channel width W₄ and nearly equal to mesa lateral width W2. For example, contact width W5 may be 80%, or more, of mesa width W2. The larger width W5 may improve top side heat extraction over the larger mesa width W2. Within p-type material 224, an electrical channel width is confined from contact width W5 to width W3, which is further confined to minimum channel width W4. In some embodiments minimum channel width W4 is at least equal to transverse waveguide width W1 and may be 1-3 times width W1, for example. Hence, for embodiments where width W1 is less than 1 μm, minimum channel width W4 may be in the range of 2-6 μm, for example. Ideally, channel widths W3-W4 are centered over width W1.

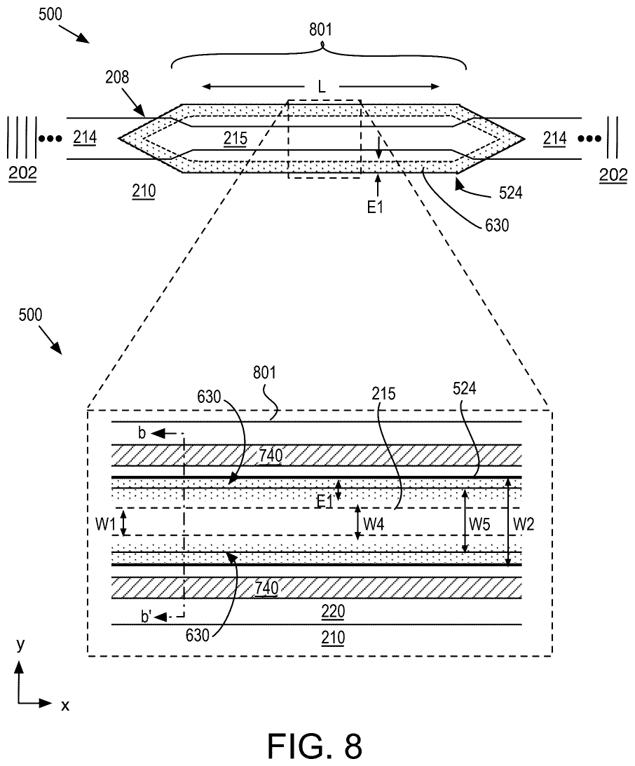

FIG. 8 further illustrates a plan view of HSQDL structure 500, in accordance with some embodiments. As shown, mesa structure 801 has a substantially constant transverse lateral width over a longitudinal length L. Length L may vary with implementation, for example from 100 μm to 1 mm, one or more aluminum oxide edge material layers 630 encircle mesa structure 801, forming a closed perimeter about a central portion of mesa structure 801. Each aluminum oxide edge material layer 630 has a substantially constant lateral width (e.g., encroachment distance E1) extending inward from sidewall 524, and may for example also be present within adiabatic tapers of optical waveguide 208. Over length L mesa structure 801 may be substantially as further illustrated within the expanded view. A layout of the HSQDL features described above is shown in the expanded view with the widths W1, W2, W4 and W5 all being substantially constant over length L.

Returning to FIG. 1, HSQDL fabrication methods 100 end at output 150 where one or more cladding materials may be formed over the active optical device structure. To further reduce the thermal resistance of the active optical structure, thick metal can be placed over one or more regions of the device. In some examples, the thick metal is electrically coupled to a contact metallization feature as both an electrical power supply rail and a topside laser heat dissipator. Combined with a wide III-V semiconductor mesa, oxidation of Al-rich material layers of an active optical device structure can improve high-temperature tolerance and performance.

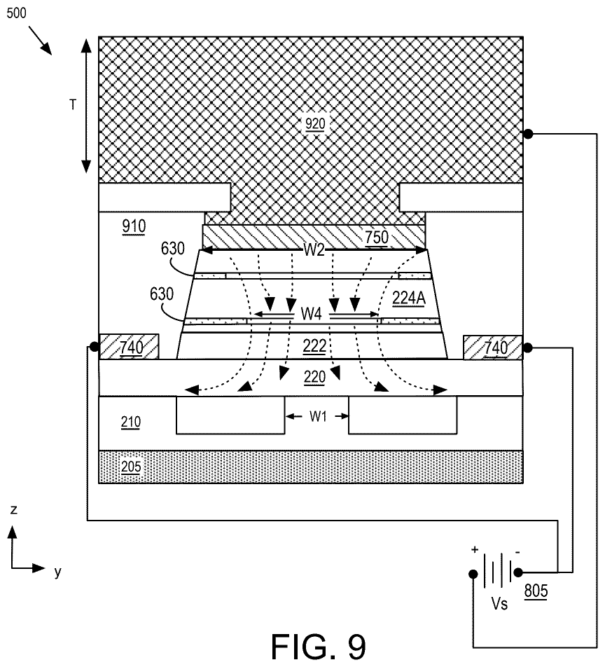

FIG. 9 illustrates a cross-sectional view of HSQDL structure 500 along a y-z plane defined by the b-b′ line illustrated in FIG. 8 following the formation of one or more cladding materials 910 and formation of interconnect metal 920. Cladding materials 910 may comprise any dielectric material (e.g., silicon-based) having suitable electrical and optical (e.g., refractive index) properties. Interconnect metal 920 is in direct contact with p-contact metallization 750. During device operation, one rail of power supply 805 may be coupled to contact metallization feature 750 through interconnect metal 920. Another rail of power supply 805 may be coupled to contact metallization features 740. When powered, aluminum oxide edge material layers 630 confine a channel current (represented by dotted arrows) to a minimum channel width W4.

Interconnect metal 920 may comprise one or more metals, such as, but not limited to, Al or Cu. Notably, interconnect metal 920 has a thickness T exceeds electrical power delivery demands of HSQDL structure 500. For example, thickness T may be 8-10 μm, or more, to enhance topside dissipation of heat extracted through mesa width W2. Interconnect metal 920 may be further coupled to a package level thermal solution (not depicted), such as an external heat spreader and/or heat exchanger, etc.

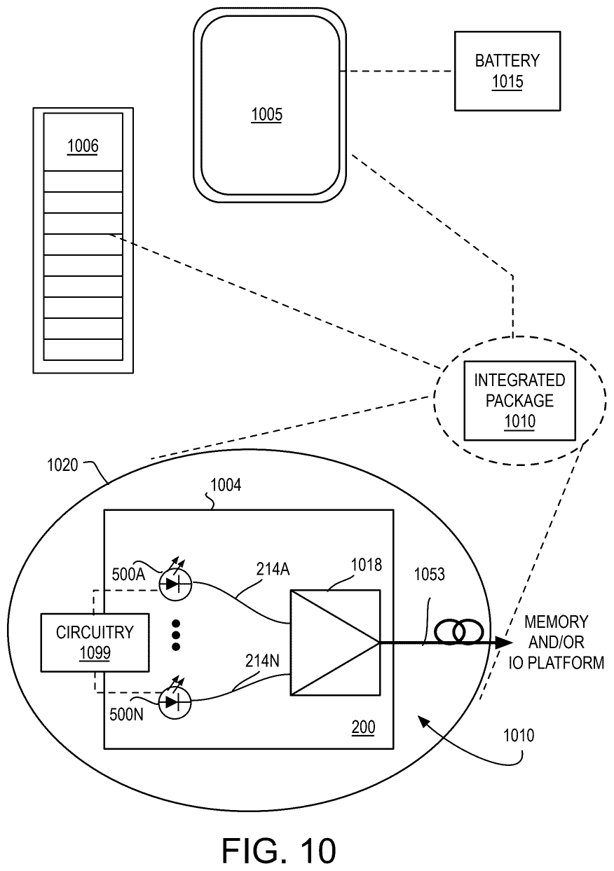

Active optical devices illustrated by the exemplary hybrid silicon structures described herein may be implemented in a wide variety of applications, systems, and platforms. FIG. 10 illustrates a mobile computing platform 1005 and data server platform 1006, each employing an optical link with one or more active hybrid silicon optical device structures comprising aluminum oxide-based current confinement, for example as described elsewhere herein. Platform 1006 may be any commercial server including any number of high-performance computing systems disposed within a rack and networked together for electronic data processing. The mobile platform 1005 may be any portable device configured for each of electronic data display, electronic data processing, wireless electronic data transmission, or the like. For example, the platform 1005 may be any of a tablet, a smart phone, laptop computer, etc., and may include an integrated or disintegrated package 1010, and a battery power supply 1015.

Platforms 1005 or 1006 may each include a PIC 1004, illustrated in expanded view 1020. PIC 1004 may be one of a plurality of PICs in package 1010, or a stand-alone packaged PIC. PIC 1004 includes a silicon waveguide-coupled HSQDL structure comprising aluminum oxide current confinement regions, in accordance with some embodiments. A plurality of wavelengths output by a plurality of HSQDL structures 500A-500N to a plurality of optical waveguides 214A-214N disposed on PIC substrate 200 may be combined with an optical multiplexer 1018 into wave division multiplexed (e.g., DWDM) optical beam. The optical beam may be coupled off-chip to an optical wire or fiber 1053, for example through a top-side coupler or edge coupler. HSQDL structures 500A-500N are electrically coupled to downstream integrated comb driver circuitry 1099, which may for example further include a voltage supply. HSQDL structures 500A-500N may output at different center wavelengths (e.g., with 0.5-1.0 nm spacing). In certain embodiments, comb driver circuitry 1099 is implemented with CMOS transistors also disposed on the substrate 200. In other embodiments, comb driver circuitry 1099 is implemented with CMOS transistors external of PIC 1004.

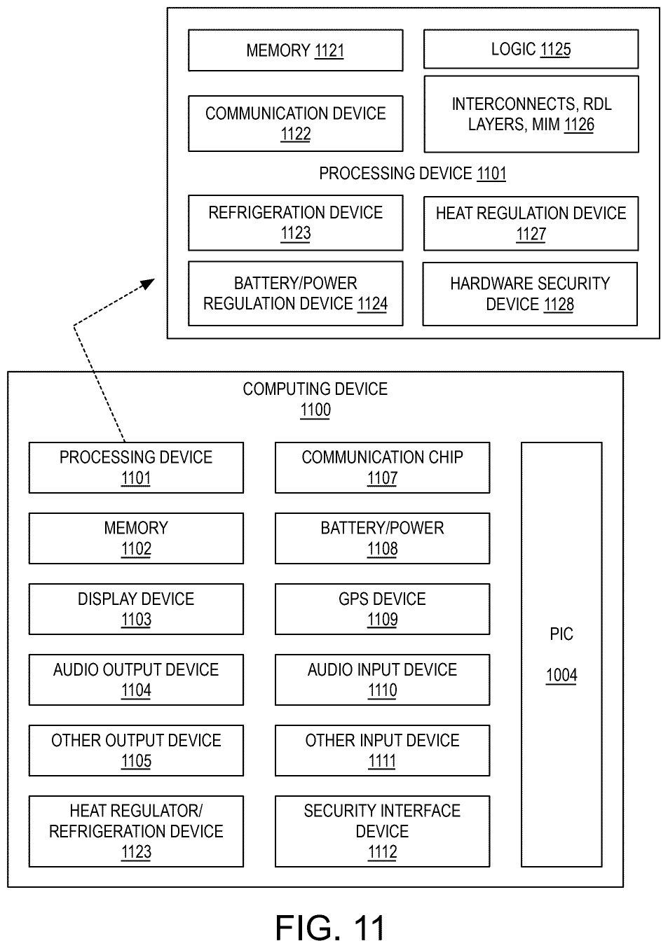

FIG. 11 is a block diagram of a cryogenically cooled computing device 1100 in accordance with some embodiments. For example, one or more components of computing device 1100 may include any of the HSQDL structures discussed elsewhere herein. A number of components are illustrated in FIG. 11 as included in computing device 1100, but any one or more of these components may be omitted or duplicated, as suitable for the application. In some embodiments, some of the components included in computing device 1100 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled.

Computing device 1100 may include a processing device 1101 (e.g., one or more processing devices). As used herein, the term processing device or processor indicates a device that processes electronic data from registers and/or memory to transform that electronic data into other electronic data that may be stored in registers and/or memory. Processing device 1101 may include a memory 1121, a communication device 1122, a refrigeration/active cooling device 1123, a battery/power regulation device 1124, logic 1125, interconnects 1126, a heat regulation device 1127, and a hardware security device 1128.

Processing device 1101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1101 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1101 shares a package with memory 1102. This memory may be used as cache memory and may include embedded dynamic random-access memory (eDRAM) or spin transfer torque magnetic random-access memory (STT-M RAM).

Computing device 1100 may include a heat regulation/refrigeration device 1123. Heat regulation/refrigeration device 1123 may maintain processing device 1101 (and/or other components of computing device 1100) at a predetermined low temperature during operation. This predetermined low temperature may be any temperature discussed elsewhere herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an optical data link comprising PIC 1004 to transmit and/or receive optical communications, for example as described elsewhere herein.

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a global positioning system (GPS) device 1109 (or corresponding interface circuitry, as discussed above). GPS device 1109 may be in communication with a satellite-based system and may receive a location of computing device 1100, as known in the art.

Computing device 1100 may include another output device 1105 (or corresponding interface circuitry, as discussed above). Examples include an audio codec, a video codec, a printer, a wired or wireless transmitter for providing information to other devices, or an additional storage device.

Computing device 1100 may include another input device 1111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, managing access lists, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples an apparatus, comprises an optical waveguide comprising silicon, and a mesa comprising a plurality of III-V material layers over the optical waveguide. A first material layer within the mesa has a greater Al content than a second material layer within the mesa. An edge material layer coplanar with the first material layer, and comprising Al and O, extends a distance into the mesa from a sidewall of the mesa. The edge material layer reduces a lateral width of the first material layer to less than a lateral width of the second material layer.

In second examples, for any of the first examples the plurality of III-V material layers comprise one or more p-type material layers and one or more III-V optical gain material layers.

In third examples, for any of the first through second examples Al content of first material layer is at least 2 at. % greater Al content of the second material layer.

In fourth examples, for any of the third examples the first material layer comprises at least 90 at. % Al, Al is substantially absent from the second material layer, and there is no edge material layer comprising Al and O coplanar with the second material layer.

In fifth examples, for any of the third through fourth examples the second material layer comprises at least 90 at. % Al. A second edge material layer coplanar with the second material layer extends into the mesa from the sidewall by a non-zero distance that is no more than one-half a distance that the first edge material layer extends into the mesa from the sidewall.

In sixth examples, for any of the third through fifth examples the first material layer consists essentially of AlₓGa₁₋ₓAs and the second material layer consists essentially of Al_{y}Ga_{1-y}As, and wherein 0≤y<x.

In seventh examples, for any of the third through sixth examples the first material layer consists essentially of AlₓIn₁₋ₓAs and the second material layer consists essentially of Al_{y}In_{1-y}As, and wherein 0≤y<x.

In eighth examples, for any of the third through seventh examples the first material layer has a thickness of 25-50 μm.

In ninth examples, for any of the first through eighth examples the first material layer and the second material layer are both p-type material layers.

In tenth examples, for any of the first through ninth examples the edge material layer encircles a perimeter of the first material layer.

In eleventh examples, for any of the tenth examples the first material layer has a first lateral width in a first dimension and wherein the second material layer has a second lateral width in the first dimension, and wherein the second lateral width is greater than the first lateral width.

In twelfth examples, for any of the eleventh examples the optical waveguide has a third lateral width, smaller than the first lateral width.

In thirteenth examples, for any of the twelfth examples the optical waveguide is crystalline silicon and has a width less than 1 μm, and a width of the mesa including the first lateral width summed with twice a width of the first edge material layer is at least 10 μm.

In fourteenth examples, for any of the thirteenth examples the width of the first edge material layer is at least 1 μm.

In fifteenth examples, for any of the first through fourteenth examples the apparatus comprises a contact metallization feature over the mesa, the contact metallization feature spanning the lateral width of the first material layer and extending over at least a portion of the edge material layer.

In sixteenth examples, a photonic integrated circuit (PIC) comprises an optical waveguide extending over a crystalline silicon substrate and a hybrid silicon-quantum dot laser (HSQDL). The HSQDL comprises a contact metallization on a mesa, the mesa comprising a stack of III-V semiconductor material layers over an active portion of the optical waveguide. The contact metallization has a first width, larger than a second width of an active portion of the optical waveguide. The stack of III-V semiconductor material layers includes one or more material layers comprising Al, a perimeter portion of which further comprises O proximal to a sidewall of the mesa.

In seventeenth examples, for any of the sixteenth examples the contact metallization overlaps the perimeter portion of layers comprising Al and further comprising O and wherein an interior portion of the one or more material layers comprising Al that lacks O has a third width, smaller than the first width.

In eighteenth examples, a method comprises forming a hybrid structure comprising a III-V material stack over an optical waveguide comprising predominantly silicon. The III-V material stack comprises a first impurity doped material over a second impurity doped material. The method comprises converting an edge portion of a first III-V material layer within the III-V material stack into a compound comprising Al and O by oxidizing the first III-V material layer from an edge of the stack. The method comprises forming a first contact to the first impurity doped material, and forming a second contact to the second impurity doped material.

In nineteenth examples, for any of the eighteenth examples the first III-V material layer is a first layer of the first impurity doped material having a first Al concentration. The method comprises converting the edge portion of the first III-V material layer retains a first interior portion of the first III-V material layer, the first interior portion comprising a first lateral width free of O. The first impurity doped material further comprises one or more second layers having a lower concentration of Al than the first Al concentration. And the one or more second layers comprise a second interior portion of a second lateral width free of O, the second lateral width greater than the first lateral width.

In twentieth examples, for any of the eighteenth through nineteenth examples the first layer comprises at least 90 at. % Al, and wherein the one or more second layers comprise an alloy of two or more of Al, Ga, In, As or P.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. An apparatus, comprising:
an optical waveguide comprising silicon; and
a mesa comprising a plurality of III-V material layers, the mesa over the optical waveguide, and wherein:
a first material layer within the mesa has a greater Al content than a second material layer within the mesa;
an edge material layer coplanar with the first material layer, and comprising Al and O, extends a distance into the mesa from a sidewall of the mesa; and
the edge material layer reduces a lateral width of the first material layer to less than a lateral width of the second material layer.

2. The apparatus of claim 1, wherein the plurality of III-V material layers comprise one or more p-type material layers and one or more III-V optical gain material layers.

3. The apparatus of claim 1, wherein Al content of first material layer is at least 2 at. % greater Al content of the second material layer.

4. The apparatus of claim 3, wherein:
the first material layer comprises at least 90 at. % Al;
Al is substantially absent from the second material layer; and
there is no edge material layer comprising Al and O coplanar with the second material layer.

5. The apparatus of claim 3, wherein
the second material layer comprises at least 90 at. % Al; and
a second edge material layer coplanar with the second material layer extends into the mesa from the sidewall by a non-zero distance that is no more than one-half a distance that the first edge material layer extends into the mesa from the sidewall.

6. The apparatus of claim 3, wherein the first material layer consists essentially of AlₓGa₁₋ₓAs and the second material layer consists essentially of Al_{y}Ga_{1-y}As, and wherein 0≤y<x.

7. The apparatus of claim 3, wherein the first material layer consists essentially of AlₓIn₁₋ₓAs and the second material layer consists essentially of Al_{y}In_{1-y}As, and wherein 0≤y<x.

8. The apparatus of claim 3, wherein the first material layer has a thickness of 25-50 μm.

9. The apparatus of claim 1, wherein the first material layer and the second material layer are both p-type material layers.

10. The apparatus of claim 1, wherein the edge material layer encircles a perimeter of the first material layer.

11. The apparatus of claim 10, wherein the first material layer has a first lateral width in a first dimension and wherein the second material layer has a second lateral width in the first dimension, and wherein the second lateral width is greater than the first lateral width.

12. The apparatus of claim 11, wherein the optical waveguide has a third lateral width, smaller
than the first lateral width.

13. The apparatus of claim 12, wherein:
the optical waveguide is crystalline silicon and has a width less than 1 μm; and
a width of the mesa including the first lateral width summed with twice a width of the first edge material layer is at least 10 μm.

14. The apparatus of claim 13, wherein the width of the first edge material layer is at least 1 μm.

15. The apparatus of claim 1, further comprising a contact metallization feature over the mesa,
the contact metallization feature spanning the lateral width of the first material layer and extending over at least a portion of the edge material layer.

16. A photonic integrated circuit (PIC), comprising:
an optical waveguide extending over a crystalline silicon substrate; and
a hybrid silicon-quantum dot laser (HSQDL), wherein the HSQDL comprises:
a contact metallization on a mesa, the mesa comprising a stack of III-V semiconductor material layers over an active portion of the optical waveguide, wherein:
the contact metallization has a first width, larger than a second width of an active portion of the optical waveguide; and
the stack of III-V semiconductor material layers includes one or more material layers comprising Al, a perimeter portion of which further comprises O proximal to a sidewall of the mesa.

17. The PIC of claim 16, wherein the contact metallization overlaps the perimeter portion of layers comprising Al and further comprising O and wherein an interior portion of the one or more material layers comprising Al that lacks O has a third width, smaller than the first width.

18. A method comprising:
forming a hybrid structure comprising a III-V material stack over an optical waveguide comprising predominantly silicon, wherein the III-V material stack comprises a first impurity doped material over a second impurity doped material;
converting an edge portion of a first III-V material layer within the III-V material stack into a compound comprising Al and O by oxidizing the first III-V material layer from an edge of the stack;
forming a first contact to the first impurity doped material; and
forming a second contact to the second impurity doped material.

19. The method of claim 18, wherein:
the first III-V material layer is a first layer of the first impurity doped material having a first Al concentration;
converting the edge portion of the first III-V material layer retains a first interior portion of the first III-V material layer, the first interior portion comprising a first lateral width free of O;
the first impurity doped material further comprises one or more second layers having a lower concentration of Al than the first Al concentration; and
the one or more second layers comprise a second interior portion of a second lateral width free of O, the second lateral width greater than the first lateral width.

20. The method of claim 18, wherein the first layer comprises at least 90 at. % Al, and wherein the one or more second layers comprise an alloy of two or more of Al, Ga, In, As or P.
